(19) United States
(12) Patent Application Publication
(10) Pub. No.: US 2025/0133828 A1
(43) Pub. Date: Apr. 24, 2025

(54) DISPLAY PANELS AND METHODS OF MANUFACTURING A DISPLAY PANEL

(71) Applicant: Guangzhou China Star Optoelectronics Semiconductor Display Technology Co., LTd., Guangzhou (CN)

(72) Inventors: Zhihui CAI, Guangzhou (CN); Shimin GE, Guangzhou (CN); Wei WU, Guangzhou (CN)

(73) Assignee: Guangzhou China Star Optoelectronics Semiconductor Display Technology Co., LTd., Guangzhou (CN)

(21) Appl. No.: 18/902,325

(22) Filed: Sep. 30, 2024

(30) Foreign Application Priority Data
Oct. 18, 2023 (CN) 202311353691.9

(51) Int. Cl. H01L 27/12

(52) U.S. Cl. CPC H10D 86/60; H10D 86/0231; H10D 86/441

(57) ABSTRACT

A display panel and a method of manufacturing a display panel are provided. The display panel includes: a substrate; a first transistor disposed on the substrate, the first transistor including a first source and a first drain; and a second transistor disposed on the substrate, the second transistor including a second source and a second drain. The first source and the first drain have two metal sub-layers respectively, and the second source and the second drain have three metal sub-layers respectively. Since the first transistor and the second transistor are both included in the display panel, the advantages of the first transistor and the second transistor are respectively utilized, thereby ensuring that the requirements of different thin film transistors for each circuit unit in the display panel are met.

### CROSS-REFERENCE TO RELATED APPLICATION

This application claims priority to and the benefit of Chinese Patent Application No. 202311353691.9, filed on Oct. 18, 2023, the disclosure of which is incorporated herein by reference in its entirety.

### TECHNICAL FIELD

The present application relates to a field of display, and in particular, to display panels, and methods of manufacturing a display panel.

### BACKGROUND

With the increasing requirements for high resolution, high definition, fast response, low power consumption and other indicators of display panels, metal oxide semiconductors are increasingly used in high-end display devices, such as Liquid Crystal Display Panel (LCD) and Organic Electroluminescence Display Panel (OLED) and so on, relying on their relatively high mobility rate and lower leakage current compared to low-temperature polysilicon. In recent years, metal oxide semiconductors with high mobility rate have become a research hotspot by further increasing their mobility rate on the basis of their low leakage current advantages.

However, since oxide semiconductors with high mobility rate are very easy to be turned on with a relatively poor stability, it is difficult to achieve an appropriate threshold voltage and excellent stability at the same time. Therefore, it is difficult to simultaneously meet different requirements for circuit units from various thin film transistors in current display panels.

### SUMMARY

Embodiments of the present application provide display panels and methods of manufacturing a display panel, which can solve the problem that it is difficult to simultaneously meet requirements for various circuit units by different thin film transistors in the current display panels when the easy turn-on and relative poor stability of high mobility oxide semiconductors make it difficult to balance appropriate threshold voltage and excellent stability.

An embodiment of the present application provides a display panel, including:
a substrate;
a first transistor disposed on the substrate, wherein the first transistor includes a first source and a first drain; and
a second transistor disposed on the substrate, wherein the second transistor includes a second source and a second drain;
wherein the first source and the first drain have two metal sub-layers respectively, and the second source and the second drain both have three metal sub-layers respectively.

Correspondingly, this application also provides a method for manufacturing a display panel, the method including:
providing a substrate; and
forming a first transistor and a second transistor on the substrate, wherein the first transistor includes a first source and a first drain, the second transistor includes a second source and a second drain, the first source and the first drain have two metal sub-layers respectively, and the second source and the second drain have three metal sub-layers respectively.

Correspondingly, the present application also provides a display panel, which is manufactured by the above method of manufacturing a display panel.

In the embodiments of the present application, a display panel and a method of manufacturing a display panel are provided, and the display panel includes: a substrate; a first transistor disposed on the substrate, the first transistor including a first source and a first drain; and a second transistor disposed on the substrate, the second transistor including a second source and a second drain. The first source and the first drain have two metal sub-layers respectively, and the second source and the second drain have three metal sub-layers respectively. In this application, the display panel includes both a first transistor and a second transistor at the same time. The second source of the second transistor has one more metal sub-layer than the first source and the first drain of the first transistor, and the second drain of the second transistor has one more metal sub-layer than the first source and the first drain of the first transistor. The first transistor has the advantages of better off-state characteristics and better stability, and the second transistor has the advantages of higher mobility and better output characteristics. In this application, since a first transistor and a second transistor are both provided in the display panel, the advantages of the first transistor and the second transistor are respectively utilized, thereby ensuring that the requirements of different thin film transistors for each circuit unit in the display panel are met.

### BRIEF DESCRIPTION OF THE DRAWINGS

In order to more clearly illustrate the technical solutions in the embodiments of the present application, the drawings referred to in the description of the embodiments will be briefly introduced below. It should be appreciated that the drawings in the following description are only some embodiments of the present application. For those skilled in the art, other drawings can also be obtained based on these drawings without exerting creative efforts.

FIG. 1 is a schematic top view of a display panel provided in a first embodiment of the present application;

FIG. 2 is a schematic cross-sectional view of a display panel provided in the first embodiment of the present application;

FIG. 3 is a characteristic curve of the first transistor provided in the first embodiment of the present application;

FIG. 4 is a characteristic curve of the second transistor provided in the first embodiment of the present application;

FIG. 5 is a schematic diagram of a GOA unit in a display panel provided in a second embodiment of the present application; and

FIG. 6 is a schematic flowchart of a method for manufacturing a display panel provided in a third embodiment of the present application.

### DETAILED DESCRIPTION

The technical solutions in the embodiments of the present application will be clearly and completely described below with reference to the accompanying drawings in the embodiments of the present application. It should be appreciated that the described embodiments are only some of the embodiments of the present application, rather than all of the embodiments. Based on the embodiments in this application, all other embodiments obtained by those skilled in the art without making creative efforts fall within the scope of protection of this application. In addition, it should be understood that the specific embodiments described here are only used to illustrate and explain the application, and are not used to limit the application. In this application, unless otherwise specified, the directional words used such as “upper” and “lower” usually refer to the upper and lower position of the device in actual use or working state, specifically the direction of the drawing in the drawings, while “inside” and “outside” refer to the outline of the device.

This application provides a display panel, and the display panel includes: a substrate; a first transistor disposed on the substrate, the first transistor including a first source and a first drain; and a second transistor disposed on the substrate, the second transistor including a second source and a second drain. The first source and the first drain have two metal sub-layers respectively, and the second source and the second drain have three metal sub-layers respectively.

This application provides a display panel, comprising: a substrate; a first transistor disposed on the substrate, wherein the first transistor includes a first source and a first drain; and a second transistor disposed on the substrate, wherein the second transistor includes a second source and a second drain; wherein the first source and the first drain have two metal sub-layers respectively, and the second source and the second drain have three metal sub-layers respectively.

This application also provides a method of manufacturing a display panel above mentioned, which will be described in detail below. It should be noted that the order of description of the following embodiments does not limit the preferred order of the embodiments.

### Embodiment 1

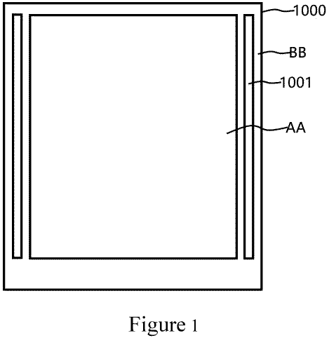

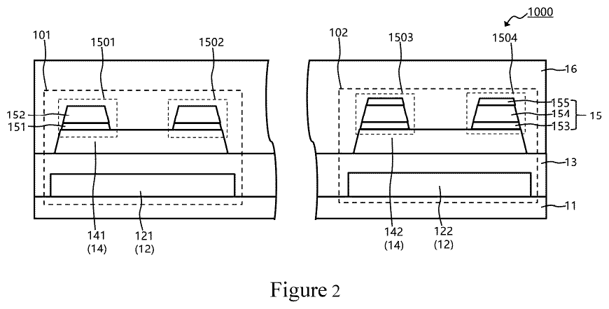

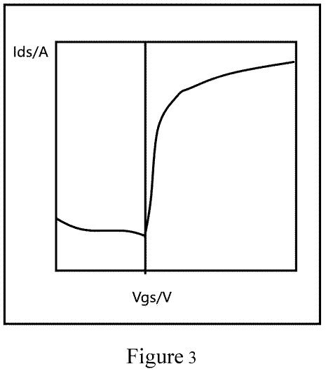

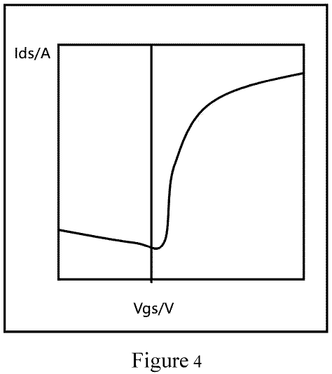

Please refer to FIGS. 1 and 2. FIG. 1 is a schematic top view of a display panel provided in Embodiment 1 of the present application. FIG. 2 is a schematic cross-sectional view of the display panel provided in Embodiment 1 of the present application. FIG. 3 is a characteristic curve of the first transistor provided in Embodiment 1 of the present application. FIG. 4 is a characteristic curve of the second transistor provided in Embodiment 1 of the present application.

This application provides a display panel 1000. The display panel 1000 includes a substrate 11, a first transistor 101, and a second transistor 102. The first transistor 101 is disposed on the substrate 11. The first transistor 101 includes a first source 1501 and a first drain 1502. The second transistor 102 is disposed on the substrate 11. The second transistor 102 includes a second source 1503 and a second drain 1504. The first source 1501 and the first drain 1502 have two metal sub-layers respectively, and the second source 1503 and the second drain 1504 have three metal sub-layers respectively.

Specifically, the inventor tested the first transistor 101 and the second transistor 102 as shown in FIG. 3 and FIG. 4. The first transistor in FIG. 3 has a first threshold voltage (Vth)=2.88V, a first mobility (mobility)=18.48 A, and a first threshold voltage shift after a long-term bias state due to positive bias temperature stress (PBTS)=2.22V. The second transistor in FIG. 4 has a second threshold voltage (Vth)=1.01V, a second mobility (mobility)=28.03 A, and a second threshold voltage shift after a long-term bias state due to positive bias temperature stress (PBTS)=3.14V. Therefore, it can be seen from the comparison that the first transistor 101 has the advantages of better off-state characteristics and better stability, but the first transistor 101 also has the disadvantages of lower mobility and worse output characteristics. Therefore, it can be seen from the comparison that the second transistor 102 has the advantages of higher mobility and better output characteristics, but the second transistor 102 has the disadvantages of worse off-state characteristics and worse stability.

It should be noted that the good stability of thin film transistors mainly means that the threshold voltage drift is small when the TFT device is in positive bias or negative bias for a long time. Good off-state characteristics of the thin film transistor means that the threshold voltage of the thin film transistor is larger, the thin film transistor is easier to turn off, and leakage current is less likely to occur.

In this embodiment, the display panel 1000 includes both a first transistor 101 and a second transistor 102. The second source 1503 and the second drain 1504 of the second transistor 102 each respectively include one more metal sub-layer than either the first source 1501 or the first drain 1502 of the first transistor 101. The first transistor 101 has the advantages of better off-state characteristics and better stability, but the first transistor 101 also has the disadvantages of lower mobility and worse output characteristics. The second transistor 102 has the advantages of higher mobility and better output characteristics, but the second transistor 102 also has the disadvantages of lower off-state characteristics and poorer stability. In this application, because both the first transistor 101 and the second transistor 102 are disposed in the display panel 1000, the advantages of the first transistor 101 and the second transistor 102 are respectively utilized, thereby ensuring that requirements of different thin film transistors for each circuit unit in the display panel 1000 can be met.

In some embodiments, the two metal sub-layers include a first metal sub-layer 151 and a second metal sub-layer 152. The second metal sub-layer 152 is disposed on a side of the first metal sub-layer 151 away from the substrate 11. The three metal sub-layers include a third metal sub-layer 153, a fourth metal sub-layer 154, and a fifth metal sub-layer 155. The fourth metal sub-layer 154 is disposed on a side of the third metal sub-layer 153 away from the substrate 11. The metal layer 155 is disposed on a side of the fourth metal sub-layer 154 away from the substrate 11. The first metal sub-layer 151 and the third metal sub-layer 153 are disposed on a same layer. The materials of the first metal sub-layer 151 and the third metal sub-layer 153 are the same. The second metal sub-layer 152 and the fourth metal sub-layer 154 are disposed on a same layer. The materials of the second metal sub-layer 152 and the fourth metal sub-layer 154 are the same.

Specifically, the first metal sub-layer 151 and the third metal sub-layer 153 are disposed on a same layer. The materials of the first metal sub-layer 151 and the third metal sub-layer 153 are the same. The second metal sub-layer 152 and the fourth metal sub-layer 154 disposed on a same layer. The material of the second metal sub-layer 152 and the fourth metal sub-layer 154 are the same. Then the first metal sub-layer 151 and the third metal sub-layer 153 can be formed through the same process step, while the second metal sub-layer 152 and the fourth metal sub-layer 154 can be formed through the same process step, which reduces the manufacturing process steps of the display panel.

Specifically, the first source 1501, the first drain 1502, the second source 1503, and the second drain 1504 can be patterned and formed through the same photomask. This can avoid increasing of the manufacturing process steps and of the number of photomasks, when the first source 1501, the first drain 1502, the second source 1503, and the second drain 1504 have different numbers of metal sub-layers. This can also reduce the manufacturing process steps and the number of photomasks of the display panel.

Specifically, in other words, the film layer structures of the display panel 1000 include a semiconductor layer 14, a first metal sub-layer 151, a second metal sub-layer 152, and a fifth metal sub-layer 155. The semiconductor layer 14 is disposed on the substrate 11. The semiconductor layer 14 includes the first semiconductor part 141 of the first transistor 101 and the second semiconductor part 142 of the second transistor 102. The first metal sub-layer 151 is disposed on the semiconductor layer 14. The second metal sub-layer 152 is disposed on the first metal sub-layer 151. The fifth metal sub-layer 155 is disposed on the second metal sub-layer 152. Among these metal sub-layers, the first metal sub-layer 151 and the second metal sub-layer 152 at least constitute the first source 1501 and the first drain 1502. Meanwhile, the first metal sub-layer 151, the second metal sub-layer 152, and the fifth metal sub-layer 155 at least constitute the source 1503 and the second drain 1504. In such case, parts of the first metal sub-layer 151 and the second metal sub-layer 152 that form the second source 1503 and the second drain 1504 are respectively called the third metal sub-layer 153 and the fourth metal sub-layer 154.

Specifically, the display panel 1000 includes a source-drain metal layer 15. The source-drain metal layer 15 includes a first metal sub-layer 151, a second metal sub-layer 152, and a fifth metal sub-layer 155 that are sequentially stacked on the semiconductor layer 14. The first source 1501 and the first drain 1502 are composed of two metal sub-layers including the first metal sub-layer 151 and the second metal sub-layer 152. The second source 1503 and the second drain 1504 are composed of three metal sub-layers including a first metal sub-layer 151, a second metal sub-layer 152, and a fifth metal sub-layer 155.

Specifically, each of the first metal sub-layer 151, the second metal sub-layer 152, and the fifth metal sub-layer 155 may include only one kind of metal element in one example. However, the first metal sub-layer 151, the second metal sub-layer 152, and the fifth metal sub-layer 155 may each include two or more metal elements in other examples.

It should be noted that, in some embodiments, an antioxidant capacity of the third metal sub-layer 153 is greater than that of the second metal sub-layer 152.

Specifically, after diligent analysis, the inventor found that in the first transistor 101, the material of the protective layer 16 manufactured later in the process usually includes an oxide insulating material. For example, the material of the protective layer 16 includes silicon oxide. When the subsequent protective layer 16 is formed, plasma is bombarded onto the surface of the second metal sub-layer 152 to form oxides of elements in the second metal sub-layer 152. Taking the second metal sub-layer 152 having copper (Cu) as an example, copper oxide (CuO) will be formed and diffused to the channel region of the first semiconductor part 141, passivating the oxygen vacancies of the oxide semiconductor. It can also be combined with defects to a certain extent and assist in forming a dense interface with the protective layer 16. In addition, this increases the resistance of the first source 1501 and the first drain 1502 and enables the first transistor 101 to have the advantages of better off-state characteristics and better stability, but this also causes the first transistor 101 to have the disadvantages of lower mobility and worse output characteristics.

Specifically, the anti-oxidation ability of the fifth metal sub-layer 155 is greater than that of the second metal sub-layer 152, as found by the inventor through diligent analysis, because the second source 1503 and the second drain 1504 in the second transistor 102 are protected by the fifth metal sub-layer 155. It was found by the inventor that when plasma bombards the surface of the fifth metal sub-layer 155, it is not easy to form oxides of elements in the fifth metal sub-layer 155. Taking the fifth metal sub-layer 155 having molybdenum (Mo) as an example, it is not easy to generate molybdenum oxide (MoO), and the sputtering and oxidation of molybdenum are reduced, so that the second transistor 102 maintains excellent mobility and output characteristics. Thus, the second transistor 102 has the advantages of higher mobility and better output characteristics, but the second transistor 102 also has disadvantages such as worse off-state characteristics and worse stability.

Specifically, an antioxidant capacity of the fifth metal sub-layer 155 is greater than that of the second metal sub-layer 152, so that the first transistor 101 and the second transistor 102 have the above-mentioned different thin film transistor characteristics.

In some embodiments, the first metal sub-layer 151 includes at least one of molybdenum, titanium, neodymium, and silver. The second metal sub-layer 152 includes at least one of copper, aluminum, and iron. The fifth metal sub-layer 155 includes at least one of molybdenum, titanium, neodymium, and silver.

Specifically, the first metal sub-layer 151 includes at least one of molybdenum, titanium, neodymium, and silver. Molybdenum, titanium, neodymium, and silver have strong oxidation resistance. Thus, it can prevent molybdenum, titanium, neodymium, and silver from producing a large amount of oxides produced during the manufacture of the two or three metal sub-layers, which can diffuse into the first semiconductor part 141 and the second semiconductor part 142.

Specifically, copper, aluminum, and iron have weak oxidation resistance, so that oxides are easily generated and diffused into the first semiconductor portion 141 when the protective layer 16 is manufactured.

Specifically, molybdenum, titanium, neodymium, and silver have strong oxidation resistance and are less likely to generate oxides diffusing to the second semiconductor portion 142 when the protective layer 16 is manufactured.

It should be noted that, in some embodiments, the material of the semiconductor layer 14 is a metal oxide semiconductor.

Specifically, FIG. 3 and FIG. 4 show measured thin film transistors of metal oxide semiconductors. The oxide of the second metal sub-layer 152 has a greater impact on the oxygen vacancies in the metal oxide semiconductor.

It should be noted that both the first transistor 101 and the second transistor 102 have a BCE (back channel etching) structure, and the semiconductor layer 14 can be implemented in a multi-layer or single-layer structure, in which a high-mobility oxide material is used for the front channel. The semiconductor layer 14 includes rare earth element doped indium gallium zinc oxide, indium zinc oxide, indium gallium oxide, indium tin zinc oxide, or crystalline oxides, and includes indium gallium zinc oxide, indium gallium oxide, indium tin zinc oxide including indium oxide, and the like. If the semiconductor layer 14 has a multi-layer structure, the back channel side oxide is made of indium gallium zinc oxide or gallium zinc oxide. If indium gallium zinc oxide is used, the ratio of indium, gallium and zinc is defined as 1:x:y, where x=1˜5, y=1˜8, and the contents of gallium and zinc are necessary to be higher than that of indium respectively. The rare earth elements in the semiconductor layer 14 include one or two of ytterbium, europium, praseodymium, terbium, cerium, dysprosium, tin, etc., and are doped with the form of their metal oxides.

In some embodiments, the film layer structure of the display panel 1000 further includes a protective layer 16, which is disposed on the two metal sub-layers and the three metal sub-layers (that is, the protective layer 16 is disposed on the second metal sub-layer 152 and the fifth metal sub-layer 155). The protective layer 16 is disposed in contact with the first source 1501, the first drain 1502, the first source 1501, and the second drain 1504.

Specifically, FIG. 2 illustrates the film layer structures of the display panel 1000 including: a substrate 11, a gate metal layer 12, a gate insulating layer 13, a semiconductor layer 14, a source-drain metal layer 15, and a protective layer 16. The gate metal layer 12 is disposed on the substrate 11. The gate metal layer 12 includes the first gate 121 of the first transistor 101 and the second gate 122 of the second transistor 102. The gate insulating layer 13 is disposed on the gate metal layer 12. The semiconductor layer 14 is disposed on the gate insulating layer 13. The semiconductor layer 14 includes a first semiconductor portion 141 of the first transistor 101 and a second semiconductor portion 142 of the second transistor 102. The two metal sub-layers are disposed on the first semiconductor portion 141. The three metal sub-layers are disposed on the second semiconductor portion 142. The protective layer 16 is disposed on the two metal sub-layers and the three metal sub-layers (that is, the protective layer 16 is disposed on the second metal sub-layer 152 and the fifth metal sub-layer 155). Also, the protective layer 16 is disposed in contact with the first source 1501, the first drain 1502, the first source 1501, and the second drain 1504.

Specifically, FIG. 2 illustrates the film layer structures of the display panel 1000 including: a substrate 11, a gate metal layer 12 disposed on the substrate 11, a gate insulating layer 13 disposed on the gate metal layer 12, and a semiconductor layer 14 disposed on the gate insulating layer 13. The source-drain metal layer 15 is disposed on the semiconductor layer 14, and the protective layer 16 is disposed on the source-drain metal layer 15. The parts of the source-drain metal layer 15 at the first transistor 101 include a first metal sub-layer 151 and the second metal sub-layer 152. The parts of the source-drain metal layer 15 at the second transistor 102 include the first metal sub-layer 151 (or the third metal sub-layer 153), the second metal sub-layer 152 (or the fourth metal sub-layer 154), and the fifth metal sub-layer 155.

Specifically, the protective layer 16 is disposed in contact with the first source 1501, the first drain 1502, the first source 1501, and the second drain 1504, so that the protective layer 16 will affect the characteristics of first transistor 101 and the second transistor 102 during manufacturing.

### Embodiment 2

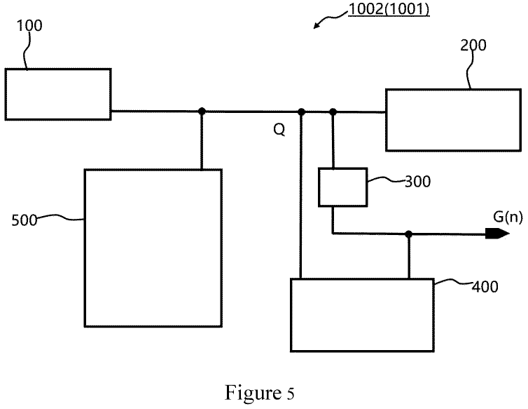

Please refer to FIG. 1 and FIG. 5. FIG. 5 is a schematic diagram of a GOA unit in a display panel provided in Embodiment 2 of the present application.

The display panel 1000 in this embodiment is the same as or similar to the display panel in any of the above embodiments. The difference lies in the further description of the characteristics of the display panel. The similarities will not be repeated here. Only the differences will be described later.

Further, in some embodiments, the display panel 1000 includes a first driving circuit, and the first driving circuit includes both the first transistor 101 and the second transistor 102.

Specifically, the first driving circuit includes a plurality of transistors, and the plurality of transistors may have different functions in the first driving circuit. For example, at least one of the transistors proposed to output or transmit signals is required as being a high-mobility transistor and therefore can be used as the second transistor 102. For example, at least one of the transistors used to maintain the potential of a certain node or location is required for high off-state characteristics, and therefore can be used as the first transistor 101.

In some embodiments, the display panel 1000 includes a gate driving circuit 1001. The gate driving circuit 1001 includes a multi-level cascaded GOA unit 1002 (gate driving circuit unit). The GOA unit includes a first transistor 101 and a second transistor 102.

Specifically, the display panel 1000 includes a gate driving circuit 1001. The gate driving circuit 1001 includes a multi-level cascade of GOA units 1002 (gate driving circuit units). The first type of driving circuit is the GOA unit 1002.

In some embodiments, the GOA unit 1002 includes a pull-up control module 100, a pull-up module 200, a pull-down module 400, and a pull-down maintenance module 500. The pull-up control module 100 is connected to the first node Q and is used to pull up the potential at the first node Q. The pull-up module 200 is connected to the first node Q, and the pull-up module 200 is used to output the scanning signal of this level (the potential at the first node Q). The pull-down module 400 is connected to the first node Q, and is used to pull down the potential at the first node Q. The pull-down maintenance module 500 is connected to the first node Q, and is used to maintain the low potential at the first node Q. At least one of the pull-up control module 100 and the pull-up module 200 includes a second transistor 102, and at least one of the pull-down module 400 and the pull-down maintenance module 500 includes a first transistor 101.

Specifically, the GOA unit 1002 may be a gate driving circuit unit in any of the related technologies. GOA unit 1002 may also include a bootstrap module 300, which may include a bootstrap capacitor.

Specifically, the pull-up control module 100 is used to pull up the potential at the first node Q, and the pull-up module 200 is used to output the scanning signal of this level (the potential at the first node Q). At least one transistor in the pull-up control module 100 and the pull-up module 200 is necessary to possess a characteristic of high mobility, while the other transistor(s) can meet its needs.

Specifically, the pull-down module 400 is used to pull down the potential at the first node Q. The pull-down maintenance module 500 is used to maintain the low potential at the first node Q. In a frame of picture, the GOA unit 1002 does not output a scanning signal most of the time, that is, the first node Q is at a low potential most of the time, and the low potential at the first node Q needs to be maintained most of the time. During the charging stage of the first node Q, it is necessary to prevent the electric charge of the first node Q from leaking, so the first transistor 101 can meet its needs.

Further, in some embodiments, the first metal sub-layer 151, the second metal sub-layer 152, and the fifth metal sub-layer 155 also constitute a data line.

Specifically, the display panel 1000 includes a data line, which is composed of three metal sub-layers: a first metal sub-layer 151, a second metal sub-layer 152, and a fifth metal sub-layer 155, so that the resistance of the data line can be reduced.

### Embodiment 3

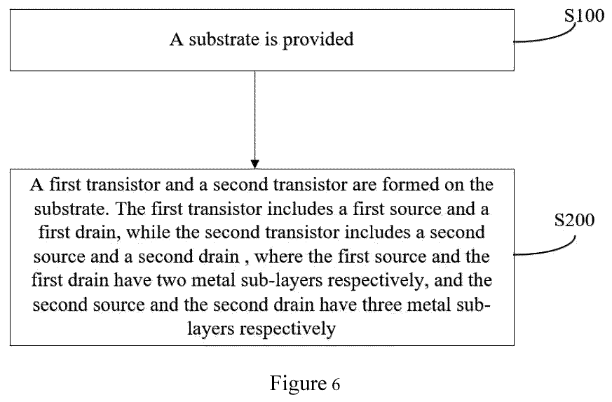

Please refer to FIG. 6, which is a schematic flowchart of a method for manufacturing a display panel according to Embodiment 3 of the present application.

The display panel 1000 in any of the above embodiments can be manufactured by the display panel manufacturing method of this embodiment.

This application also provides a method for manufacturing a display panel, the method including the steps: S100, and S200.

In S100, a substrate 11 is provided.

In S200, a first transistor 101 and a second transistor 102 are formed on the substrate 11. The first transistor 101 includes a first source 1501 and a first drain 1502, the second transistor 102 includes a second source 1503 and a second drain 1504, the first source 1501 and the first drain 1502 have two metal sub-layers respectively, and the second source 1503 and the second drain 1504 have three metal sub-layers respectively.

Specifically, the step S200 of forming the first transistor 101 and the second transistor 102 on the substrate 11 may include the sub-steps: S101, S102, S103, and S104. A gate metal layer 12 is formed on the substrate 11 in S101. The gate metal layer 12 includes the first gate 121 of the first transistor 101 and the second gate 122 of the second transistor 102. A gate insulating layer 13 is formed on the gate metal layer 12 in S102. A semiconductor layer 14 is formed on the gate insulating layer 13 in S103. The semiconductor layer 14 includes the first semiconductor part 141 of the first transistor 101 and the second semiconductor part 142 of the second transistor 102. The first source 1501 and the first drain 1502 of the first transistor 101, and the second source 1503 and the second drain 1504 of the second transistor 102, are formed on the first semiconductor part 141 in S104, where the first source 1501 and the first drain 1502 have two metal sub-layers respectively, and the second source 1503 and the second drain 1504 have three metal sub-layers respectively.

In some embodiments, in step S200, the two metal sub-layers include a first metal sub-layer 151 and a second metal sub-layer 152. The second metal sub-layer 152 is disposed on a side of the first metal sub-layer 151 away from the substrate 11. The three metal sub-layers include a third metal sub-layer 153, a fourth metal sub-layer 154, and a fifth metal sub-layer 155. The fourth metal sub-layer 154 is disposed on a side of the third metal sub-layer 153 away from the substrate 11. The fifth metal sub-layer 155 is disposed on the side of the fourth metal sub-layer 154 away from the substrate 11. In particular, for forming the first source 1501, the first drain 1502, the second source 1503, and the second drain 1504, step S200 can include the sub-steps: S201, S202, and S203. In S201, the first metal pattern and the second metal pattern are sequentially deposited on the substrate 11. In S202, a third metal pattern is formed on the second metal pattern in the area corresponding to the second transistor 102 through a metal printing process. In S203, the first metal pattern, the second metal pattern, and the third metal pattern are patterned to form the first metal sub-layer 151, the second metal sub-layer 152, the third metal sub-layer 153, the fourth metal sub-layer 154, and the fifth metal sub-layer 155.

Specifically, the first metal sub-layer 151 and the second metal sub-layer 152 are formed in the area corresponding to the first transistor 101 through the first metal pattern and the second metal pattern respectively (or in other words, the first source 1501 and the first drain 1502 are formed in the area corresponding to the first transistor 101 through the first metal pattern and the second metal pattern). The third metal sub-layer 153, the fourth metal sub-layer 154, and the fifth metal sub-layer 155 are formed in the area corresponding to the second transistor 102 through the first metal pattern, the second metal pattern and the third metal pattern respectively (or in other words, the second source 1503 and the second drain 1504 are formed in the area corresponding to the second transistor 102 through the first metal pattern, the second metal pattern, and the third metal pattern). Moreover, the first metal sub-layer 151 and the third metal sub-layer 153 are disposed on a same layer and are made of a same material, and the second metal sub-layer 152 and the fourth metal sub-layer 154 are disposed on a same layer and are made of a same material.

Specifically, the third metal pattern is formed on the second metal pattern in the corresponding area of the second transistor 102 through a metal printing process (printing process).

In some other embodiments, in step S200, the two metal sub-layers include a first metal sub-layer 151 and a second metal sub-layer 152. The second metal sub-layer 152 is disposed on a side of the first metal sub-layer 151 away from the substrate 11. The three metal sub-layers include a third metal sub-layer 153, a fourth metal sub-layer 154, and a fifth metal sub-layer 155. The fourth metal sub-layer 154 is disposed on a side of the third metal sub-layer 153 away from the substrate 11. The fifth metal sub-layer 155 is disposed on the side of the fourth metal sub-layer 154 away from the substrate 11. In particular, for forming the first source 1501, the first drain 1502, the second source 1503, and the second drain 1504, step S200 can include the sub-steps: S21, S22, and S23. In S21, the first metal pattern, the second metal pattern, and the third metal pattern are sequentially deposited on the substrate 11. In S22, the first metal pattern, the second metal pattern, and the third metal pattern are patterned to form the first metal sub-layer 151, the second metal sub-layer 152, the third metal sub-layer 153, the fourth metal sub-layer 154, and the fifth metal sub-layer 155. In S23, the third metal pattern is etched on the side of the second metal sub-layer 152 away from the first metal sub-layer 151.

Specifically, in step S23, by etching the third metal pattern on the side of the second metal sub-layer 152 away from the first metal sub-layer 151, the third metal pattern on the second metal sub-layer 152 in the area corresponding to the first transistor 101 is removed, such that the first source 1501 and the first drain 1502 have two metal sub-layers respectively.

After step S200, step S300 may be further included to form the protective layer 16 on the first source 1501, the first drain 1502, the second source 1503, and the second drain 1504. The protective layer 16 is made of insulating material.

### Embodiment 4

This application also provides a display panel manufactured by the display panel manufacturing method described in any possibilities of Embodiment 3.

The above is a detailed introduction to a display panel and its manufacturing method provided by the embodiments of the present application. Specific examples are used in this article to illustrate the principles and implementation manners of the present application. The description of the above embodiments is only used to help understand the present application and core ideas. At the same time, changes in the specific implementation and application scope based on the ideas of the present application are apparent to those skilled in the art. In summary, the content in this description should not be understood as a limitation of the present application.

What is claimed is:

1. A display panel, comprising:
a substrate;
a first transistor disposed on the substrate, wherein the first transistor comprises a first source and a first drain; and
a second transistor disposed on the substrate, wherein the second transistor comprises a second source and a second drain;
wherein the first source and the first drain have two metal sub-layers respectively, and the second source and the second drain have three metal sub-layers respectively.

2. The display panel according to claim 1, wherein the two metal sub-layers comprise a first metal sub-layer and a second metal sub-layer, and the second metal sub-layer is disposed on a side of the first metal sub-layer away from the substrate;
wherein the three metal sub-layers comprise a third metal sub-layer, a fourth metal sub-layer, and a fifth metal sub-layer; the fourth metal sub-layer is disposed on a side of the third metal sub-layer away from the substrate; and the fifth metal sub-layer is disposed on a side of the fourth metal sub-layer away from the substrate; and
wherein the first metal sub-layer and the third metal sub-layer are disposed on a same layer and made of a same material, the second metal sub-layer and the fourth metal sub-layer are disposed on a same layer and made of a same material.

3. The display panel according to claim 2, wherein the first metal sub-layer comprises at least one of molybdenum, titanium, neodymium, and silver;
wherein the second metal sub-layer comprises at least one of copper, aluminum, and iron; and
wherein the fifth metal sub-layer comprises at least one of molybdenum, titanium, neodymium, and silver.

4. The display panel according to claim 1, further comprising:
a protective layer disposed on the two metal sub-layers and the three metal sub-layers, wherein the protective layer is respectively connected to the first source, the first drain, the first source and the second drain.

5. The display panel according to claim 1, wherein the display panel comprises a gate drive circuit, the gate drive circuit comprises a multi-level cascade of GOA unit, and the GOA unit comprises a first transistor and a second transistor.

6. The display panel according to claim 5, wherein the GOA unit comprises:
a pull-up control module connected to a first node and used to pull up a potential at the first node;
a pull-up module connected to the first node and used to output a scanning signal of the potential at the first node;
a pull-down module connected to the first node and used to pull down the potential at the first node; and
a pull-down maintenance module connected to the first node and used to maintain a low potential at the first node;
wherein at least one of the pull-up control module and the pull-up module comprises the second transistor, and at least one of the pull-down module and the pull-down maintenance module comprises the first transistor.

7. A method of manufacturing a display panel, the method comprising:
providing a substrate; and
forming a first transistor and a second transistor on the substrate, wherein the first transistor comprises a first source and a first drain, the second transistor comprises a second source and a second drain, the first source and the first drain have two metal sub-layers respectively, and the second source and the second drain have three metal sub-layers respectively.

8. The method of manufacturing a display panel according to claim 7, wherein the two metal sub-layers comprise a first metal sub-layer and a second metal sub-layer, and the second metal sub-layer is disposed on a side of the first metal sub-layer away from the substrate;
wherein the three metal sub-layers comprise a third metal sub-layer, a fourth metal sub-layer, and a fifth metal sub-layer, the fourth metal sub-layer is disposed on a side of the third metal sub-layer away from the substrate, and the fifth metal sub-layer is disposed on a side of the fourth metal sub-layer away from the substrate; and
wherein forming the first source, the first drain, the second source, and the second drain comprises:
sequentially depositing a first metal pattern and a second metal pattern on the substrate;
forming a third metal pattern on the second metal pattern in the area corresponding to the second transistor through a metal printing process; and
patterning the first metal pattern, the second metal pattern, and the third metal pattern to form the first metal sub-layer, the second metal sub-layer, the third metal sub-layer, the fourth metal sub-layer, and the fifth metal sub-layer.

9. The method of manufacturing a display panel according to claim 7, wherein the two metal sub-layers comprise a first metal sub-layer and a second metal sub-layer, and the second metal sub-layer is disposed on a side of the first metal sub-layer away from the substrate;
wherein the three metal sub-layers comprise a third metal sub-layer, a fourth metal sub-layer, and a fifth metal sub-layer, the fourth metal sub-layer is disposed on a side of the third metal sub-layer away from the substrate, and the fifth metal sub-layer is disposed on a side of the fourth metal sub-layer away from the substrate; and
wherein forming the first source, the first drain, the second source, and the second drain comprises:
sequentially depositing a first metal pattern, a second metal pattern, and a third metal pattern on the substrate;
patterning the first metal pattern, the second metal pattern, and the third metal pattern to form the first metal sub-layer, the second metal sub-layer, the third metal sub-layer, the fourth metal sub-layer, and the fifth metal sub-layer; and
etching the third metal pattern on a side of the second metal sub-layer away from the first metal sub-layer.

10. A display panel, made by the method of manufacturing the display panel the method comprising:
providing a substrate; and
forming a first transistor and a second transistor on the substrate, wherein the first transistor comprises a first source and a first drain, the second transistor comprises a second source and a second drain, the first source and the first drain have two metal sub-layers respectively, and the second source and the second drain have three metal sub-layers respectively.
